(19) United States
(12) Patent Application Publication
(10) Pub. No.: US 2010/0166437 A1
(43) Pub. Date: Jul. 1, 2010

(54) Optical detecting circuit, optical transmitting apparatus, and optical detecting method

(75) Inventor: Kazukiyo Ogawa, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/585,351

(22) Filed: Sep. 11, 2009

Related U.S. Application Data
(63) Continuation of application No. PCT/JP2007/055043, filed on Mar. 14, 2007.

(51) Int. Cl. H04B 10/04; H03F 3/08; H01L 31/09

(52) U.S. Cl. 398/192; 250/214 A

(57) ABSTRACT

An optical detecting circuit includes a PD receiving unit generating voltage depending on an optical level of input light, a high range amplifying unit amplifying the generated voltage, a low range amplifying unit amplifying the generated voltage by a gain larger than that of the high range amplifying unit, an A/D converting unit digitizing voltage levels of the output voltages of the high range amplifying unit and the low range amplifying unit, a selecting unit comparing the A/D conversion results with thresholds to select for output one of the digitized values of the voltage levels of the output voltages of the high range amplifying unit and the low range amplifying unit, and an output correcting unit obtaining a correction value depending on the selection result from a correcting table to add the correction value to the value selected by the selecting unit.

### CROSS-REFERENCE TO RELATED APPLICATION

This application is a continuation of PCT international application Ser. No. PCT/JP2007/055043 filed on Mar. 14, 2007 which designates the United States, the entire contents of which are incorporated herein by reference.

### FIELD

The embodiments discussed herein are directed to an optical detecting circuit, an optical transmitting apparatus and an optical detecting method.

### BACKGROUND

In recent years, as a transmitting apparatus that transmits optical signals via an optical network, a wavelength division multiplexing (WDM) transmitting apparatus is becoming widely used. The WDM transmitting apparatus is an apparatus that can transmit the optical signals having a plurality of wavelengths using wavelength-division multiplex technique, resulting in increased communication capacity per line.

Some of the WDM transmitting apparatuses include an optical amplifier that enables to communicate over long distance. The WDM transmitting apparatus including such optical amplifier performs automatic gain control (AGC) to keep an optical level (intensity of light) of the optical signals output from the optical amplifier constant.

The automatic gain control of the optical amplifier is accomplished by an electrical circuit. That is, the optical level at an output of the optical amplifier is converted to a voltage level by a receiving unit including a photodiode (PD) or photo-detector. The electrical circuit compares this voltage level with a reference value to correct a gain of the optical amplifier based on the comparison result.

Improving the accuracy of the automatic gain control is important to accomplish stabilized long distance communication. However, exponential function characteristics of an output of the photodiode become a problem. The photodiode has a smaller output and a lower resolution with decreased optical input level, tending to have larger controlling error. To solve this problem, a technique that uses a logarithmic amplifier to amplify the output of the photodiode is known (for example, Japanese Laid-open Patent Publication No. 2003-249895)

The logarithmic amplifier is larger in size and expensive as compared with the operational amplifier commonly used as the amplifier, resulting in increased circuit size and costs. In particular, the technique disclosed in Japanese Laid-open Patent Publication No. 2003-249895 requires two logarithmic amplifiers in combination to improve output characteristics of the logarithmic amplifier, which significantly affects the circuit size and costs.

### SUMMARY

According to an aspect of an embodiment of the present invention, an optical detecting circuit that detects and outputs an optical level of input light includes an optical receiving unit that generates voltage depending on the optical level of the input light, a first amplifying unit that amplifies the voltage generated by the optical receiving unit, a second amplifying unit that amplifies the voltage generated by the optical receiving unit by a gain larger than that of the first amplifying unit, an A/D converting unit that digitizes voltage levels of output voltages of the first amplifying unit and the second amplifying unit, a selecting unit that compares conversion results of the A/D converting unit with a threshold to select for output one of digitized values of the voltage levels of the output voltages of the first amplifying unit and the second amplifying unit, and an output correcting unit that obtains a correction value depending on a selection result of the selecting unit from a storage unit to add the correction value to the value selected by the selecting unit.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of a WDM transmitting apparatus;

FIG. 2 is a block diagram of an optical detecting circuit according to an embodiment;

FIG. 3 is a schematic of a PD receiving unit and an electrical level stabilizing unit;

FIG. 4 is a graph for explaining resolutions obtained when a gain of a low range amplifying unit is five;

FIG. 5 is a graph for explaining resolutions obtained when the gain of the low range amplifying unit is 20;

FIG. 6 is a graph for explaining resolutions obtained when the gain of the low range amplifying unit is 100;

FIG. 7 is an exemplary converting table;

FIG. 8 is a block diagram of the optical detecting circuit including six photodiodes;

FIG. 9 is a block diagram of a conventional optical detecting circuit;

FIG. 10 is a schematic of the PD receiving unit; and

FIG. 11 is a block diagram of another conventional optical detecting circuit.

### DESCRIPTION OF EMBODIMENT

Exemplary embodiments of an optical detecting circuit, an optical transmitting apparatus, and an optical detecting method according to the present invention are described below in greater detail with reference to the accompanying drawings.

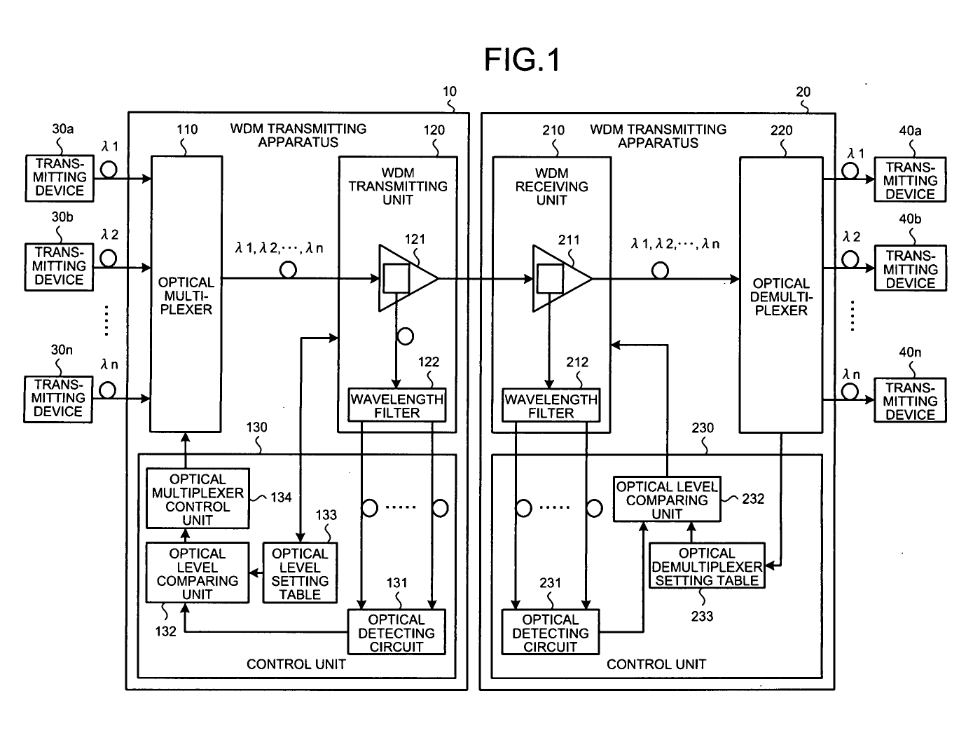

A WDM transmitting apparatus will now be explained. FIG. 1 is a block diagram of a WDM transmitting apparatus. For simplicity, in FIG. 1, a WDM transmitting apparatus 10 includes only components used to transmit optical signals and a WDM transmitting apparatus 20 includes only components used to receive the optical signals. It is possible to realize a WDM apparatus capable of transmitting and receiving the optical signals by including both groups of the components.

As depicted in FIG. 1, the WDM transmitting apparatus 10 has an optical multiplexer 110, a WDM transmitting unit 120, and a control unit 130. The optical multiplexer 110 is a processor that wavelength-division multiplexes optical signals transmitted from transmitting devices 30a to 30n. The transmitting devices 30a to 30n are, for example, synchronous digital hierarchy (SDH) transmitting devices and transmit the optical signals having different wavelengths λ1 to λn to the WDM transmitting apparatus 10.

The WDM transmitting unit 120 transmits the optical signals multiplexed by the optical multiplexer 110 to a counter apparatus (in this example, the WDM transmitting apparatus 20). The WDM transmitting unit 120 has an optical amplifier 121 and a wavelength filter 122. The optical amplifier 121 amplifies the optical signals to compensate attenuation experienced in a channel and amplifies the optical signals as they are without converting the optical signals to electrical signals. The optical signals amplified by the optical amplifier 121 are transmitted to the counter apparatus. The amplified optical signals are also branched and input to the wavelength filter 122 for automatic gain control. The wavelength filter 122 isolates each wavelength contained in the input optical signals.

The control unit 130 performs the automatic gain control and has an optical detecting circuit 131, an optical level comparing unit 132, an optical level setting table 133, and an optical multiplexer control unit 134. The optical detecting circuit 131 detects an optical level of the optical signal of each wavelength isolated by the wavelength filter 122.

The optical level comparing unit 132 compares the optical levels detected by the optical detecting circuit 131 with values set in the optical level setting table 133 to indicate resulting differences to the optical multiplexer control unit 134. The optical multiplexer control unit 134 controls an output of the optical multiplexer control unit 134 according to the indicated differences.

The WDM transmitting apparatus 20 has a WDM receiving unit 210, an optical demultiplexer 220, and a control unit 230. The WDM receiving unit 210 receives the optical signals transmitted from a counter apparatus (in this example, the WDM transmitting apparatus 10). The WDM receiving unit 210 has an optical amplifier 211 and a wavelength filter 212.

The optical amplifier 211 amplifies the optical signals to compensate attenuation experienced in the channel and amplifies the optical signals as they are without converting the optical signals to the electrical signals. The optical signals amplified by the optical amplifier 211 are transmitted to the optical demultiplexer 220. The amplified optical signals are also branched and input to the wavelength filter 212 for the automatic gain control. The wavelength filter 212 isolates each wavelength contained in the input optical signals.

The optical demultiplexer 220 demultiplexes the wavelength-division multiplexed optical signals to obtain the optical signals having each wavelength before multiplexing and transmits the obtained optical signals to transmitting devices 40a to 40n. The transmitting devices 40a to 40n are, for example, the SDH transmitting devices and receive the optical signals having different wavelengths λ1 to λn from the WDM transmitting apparatus 20.

The control unit 230 performs the automatic gain control and has an optical detecting circuit 231, an optical level comparing unit 232, and an optical demultiplexer setting table 233. The optical detecting circuit 231 detects an optical level of the optical signal of each wavelength isolated by the wavelength filter 212. The optical level comparing unit 232 compares the optical levels detected by the optical detecting circuit 231 with values set in the optical demultiplexer setting table 233 to control an output of the optical amplifier 211 according to the resulting differences.

In this way, in the WDM transmitting apparatuses, in both sides of transmitting and receiving the optical signals, output optical levels from the optical amplifiers are subjected to the automatic gain control and the optical detecting circuits are used to detect the output optical level of the optical amplifiers.

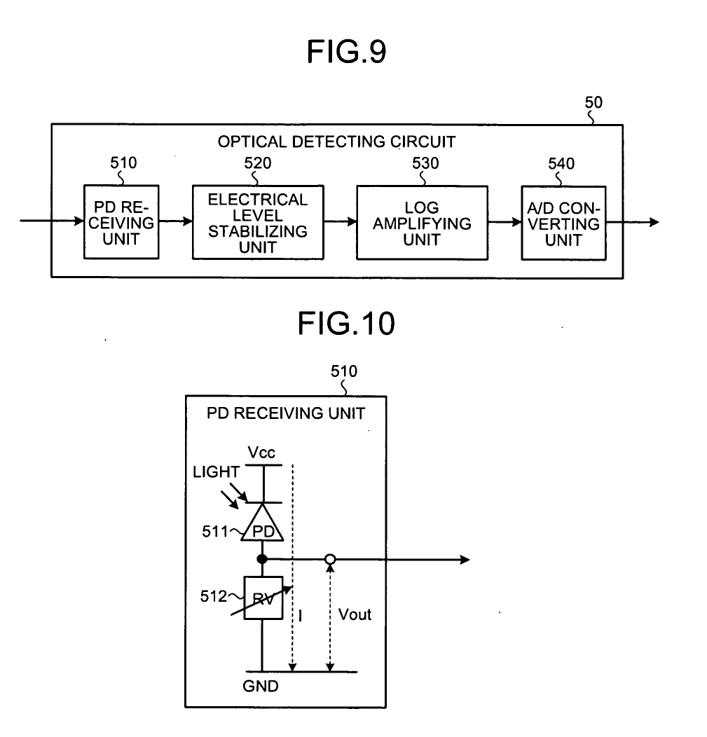

A conventional optical detecting circuit is explained. FIG. 9 is a block diagram of a conventional optical detecting circuit 50. The optical detecting circuit 50 corresponds to the optical detecting circuit 131 and the optical detecting circuit 231 depicted in FIG. 1. The optical detecting circuit 50 has a PD receiving unit 510, an electrical level stabilizing unit 520, a logarithmic amplifying unit 530, and an A/D converting unit 540.

The PD receiving unit 510 is a processor that converts the optical levels of the input optical signals to voltage levels. As depicted in FIG. 10, the PD receiving unit 510 has a PD 511 and a variable resistor 512. The PD 511 generates current (I) when receiving light with voltage (Vcc) being applied thereto. Then, the variable resistor 512, which is a driving resistor of the PD 511, generates voltage (Vout) having a magnitude that depends on the generated current.

The PD 511 has characteristics that convert the input optical levels in dB/dBm to electric power in watt. Amount of current generated per unit electric power is referred to as photodetection sensitivity (in mA/W). The output voltage (Vout) of the PD receiving unit 510 is calculated as Equation (1):

Vout=Popt×η×RV (1)

where Popt is an electrical power value converted from the PD received optical level, η is a photodetection sensitivity of the PD, and RV is a PD driving resistance. Each of these parameters is expressed in the following general unit.

Vout: mV

Popt: mW

η: mA/mW

RV: Q

The PD 511 has exponential function characteristics, which are inherent characteristics of a diode. The output voltage (Vout) of the PD receiving unit 510 becomes lower as the input optical level decreases. The photodetection sensitivity of the PD 511 depends on characteristics of PD device itself. In particular, some PD devices have wide sensitivity range of 0.01 to 0.07 mA/mW and others have narrow sensitivity range of 0.02 to 0.04 mA/mW. The variable resistor 512 has a resistance set to generate voltage having a magnitude suitable for a processor located downstream depending on the photodetection sensitivity of the PD 511.

The output (Vout) of the PD receiving unit 510 is stabilized by the electrical level stabilizing unit 520. The exponential function characteristics of the output are corrected by the logarithmic amplifying unit 530 to be signals suitable for comparison processing, for example, in the optical level comparing unit 132. Then, the output of the PD receiving unit 510 is converted to digital signals indicating a magnitude of the voltage level by the A/D converting unit 540 and then output.

In this way, in the conventional optical detecting circuit 50, the fluctuation in the photodetection sensitivity of the PD 511 is corrected by the variable resistor 512 and the exponential function characteristics of the output of the PD receiving unit 510 are corrected by the logarithmic amplifying unit 530. However, as generally known, the accuracy of the variable resistor 512 varies about ±20% at least. The accuracy of the output of the optical detecting circuit 50 is degraded by this percent. In addition, the logarithmic amplifier used as the logarithmic amplifying unit 530 is a component that is large in size and expensive, leading to increased costs of the optical detecting circuit 50.

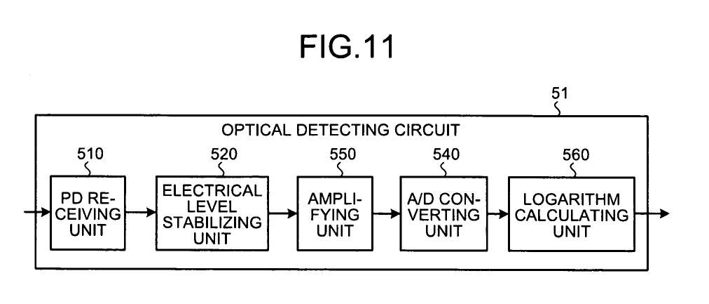

FIG. 11 is a block diagram of another conventional optical detecting circuit 51. The optical detecting circuit 51 is a circuit that corresponds to the optical detecting circuit 131 and the optical detecting circuit 231 depicted in FIG. 1. The optical detecting circuit 51 has the PD receiving unit 510, the electrical level stabilizing unit 520, an amplifying unit 550, the A/D converting unit 540, and a logarithm calculating unit 560.

The optical detecting circuit 51 is different from the optical detecting circuit 50 in that the optical detecting circuit 51 includes the amplifying unit 550 that amplifies voltage using a typical operational amplifier instead of the logarithmic amplifying unit 530 and the exponential function characteristics of the output of the PD receiving unit 510 are digitally calculated and processed in the logarithm calculating unit 560 provided downstream of the A/D converting unit 540.

However, also in this configuration, the problem of reduced output accuracy resulted from the variable resistor 512, which corrects fluctuation of receiving sensitivity of the PD 511, being provided in the PD receiving unit 510 is not solved. In addition, the logarithm calculating unit 560 is a large circuit. Therefore, the problem with the circuit size and the costs is not solved.

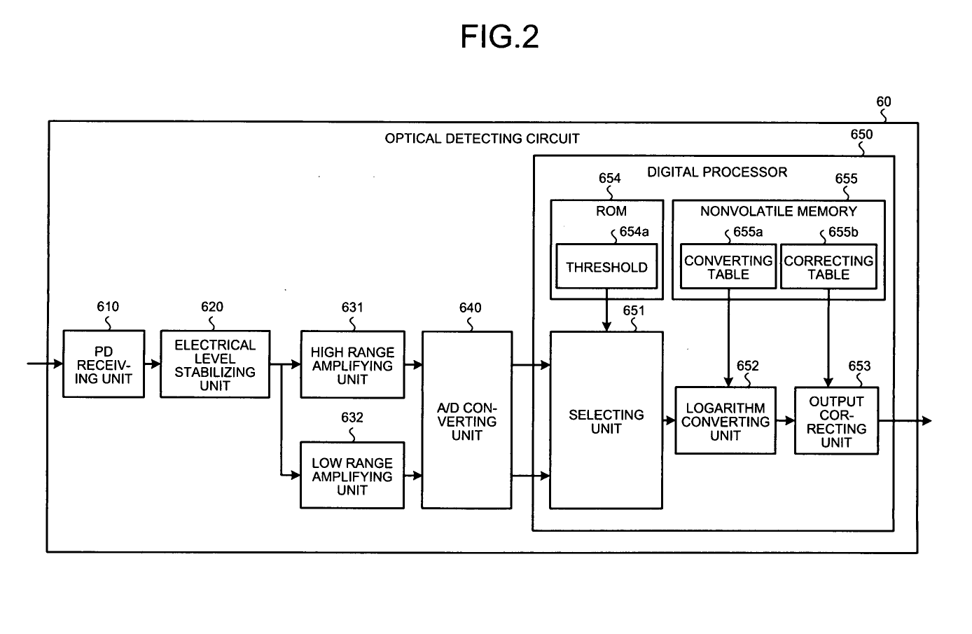

An optical detecting circuit 60 according to the present embodiment is explained. FIG. 2 is a block diagram of the optical detecting circuit 60 according to the present embodiment. The optical detecting circuit 60 is a circuit that corresponds to the optical detecting circuit 131 and the optical detecting circuit 231 depicted in FIG. 1. The optical detecting circuit 60 has a PD receiving unit 610, an electrical level stabilizing unit 620, a high range amplifying unit 631, a low range amplifying unit 632, an A/D converting unit 640, and a digital processor 650.

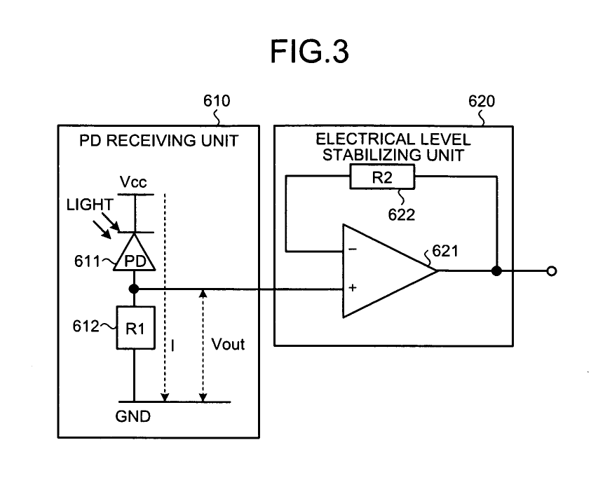

The PD receiving unit 610 is a processor that converts the optical level of the input optical signals to voltage levels. As depicted in FIG. 3, the PD receiving unit 610 has a PD (photodiode or photo-detector) 611 and a fixed resistor 612. In this way, the PD receiving unit 610 uses, instead of the variable resistor, the fixed resistor as a resistor that, from the PD 611, generates voltage having a magnitude suitable for the processor located downstream thereof. Therefore, the problem with the output accuracy of the optical detecting circuit 60 resulted from the variable resistor can be solved.

The electrical level stabilizing unit 620 is a processor that stabilizes the output of the PD receiving unit 610. As depicted in FIG. 3, the electrical level stabilizing unit 620 has an operational amplifier 621 and a fixed resistor 622.

Selection of the fixed resistor 612 is explained. The output voltage of the PD receiving unit 610 has to have a magnitude suitable for the processor located downstream thereof. More precisely, the output voltage of the PD receiving unit 610 has to have voltage higher than an input offset voltage of the operational amplifier 621 in the electrical level stabilizing unit 620 to obtain a sufficient gain.

The output voltage of the PD receiving unit 610 has to be a voltage such that the voltage amplified by the high range amplifying unit 631 is equal to or less than a full scale (a measurable upper limit) of the A/D converting unit 640. This is because, when the voltage amplified by the high range amplifying unit 631 exceeds the full scale of the A/D converting unit 640, the optical level of the input optical signal cannot be measured.

The high range amplifying unit 631 and the low range amplifying unit 632 are processors that amplify the output voltage of the electrical level stabilizing unit 620. The high range amplifying unit 631 and the low range amplifying unit 632 have different gains. More precisely, the high range amplifying unit 631 has a gain such that the maximum voltage output from the electrical level stabilizing unit 620 is just fitted in the full scale of the A/D converting unit 640, resulting in improved dynamic range.

On the other hand, the low range amplifying unit 632 has a gain such that sufficient resolution can be obtained for low voltage output from the electrical level stabilizing unit 620. As previously explained, the output voltage of the PD receiving unit 610 has the exponential function characteristics. Therefore, as the optical level of the input optical signals becomes smaller, the output voltage of the PD receiving unit 610 and the resolution also become smaller. Thus, the low range amplifying unit 632 has a gain higher than that of the high range amplifying unit 631 to amplify the output voltage of the PD receiving unit 610 in large scale, resulting in improved resolution at a low output level.

The combination of gains of the high range amplifying unit 631 and the low range amplifying unit 632 can be determined depending on the characteristics of the PD 611, required accuracy, or the like. The exemplary combination of gains of the high range amplifying unit 631 and the low range amplifying unit 632 are shown. In the example explained below, the full scale of the A/D converting unit 640 is 4000 millivolts, the output offset voltage of the operational amplifier 621 in the electrical level stabilizing unit 620 is 10 millivolts, and the gain of the high range amplifying unit 631 is one.

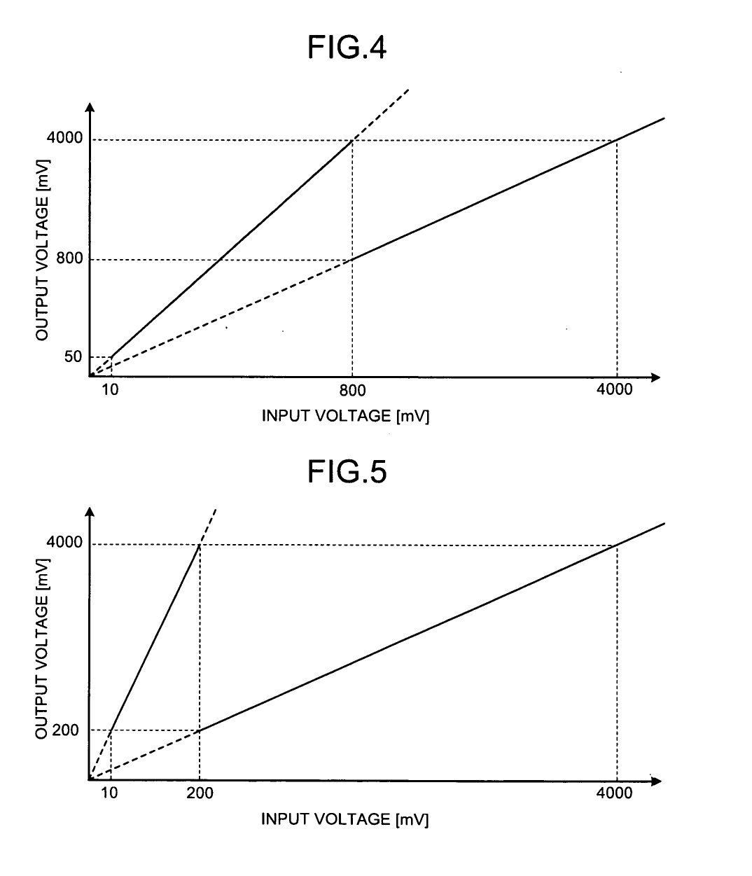

FIG. 4 is a graph for explaining resolutions obtained when the gain of the low range amplifying unit 632 is five. As depicted in FIG. 4, in this case, the minimum output voltage of the high range amplifying unit 631 will be 800 millivolts and the resolution will be 0.005 dB/step. The minimum output voltage of the low range amplifying unit 632 will be 50 millivolts and the resolution will be 0.086 dB/step.

FIG. 5 is a graph for explaining resolutions obtained when the gain of the low range amplifying unit 632 is 20. As depicted in FIG. 5, both of the output voltages of the high range amplifying unit 631 and low range amplifying unit 632 will be 200 millivolts and the resolutions will be 0.022 dB/step.

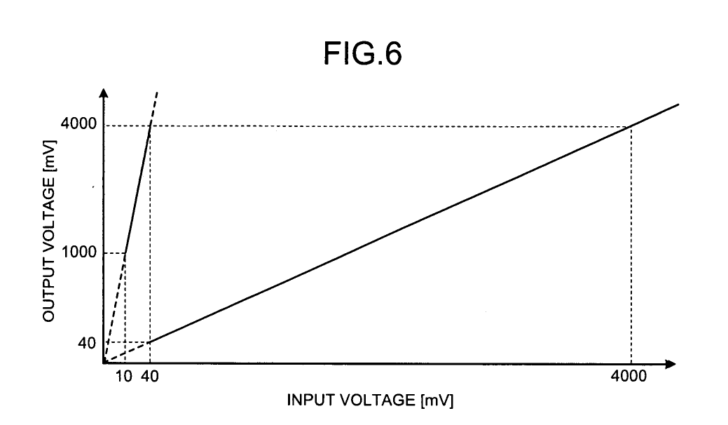

FIG. 6 is a graph for explaining resolutions obtained when the gain of the low range amplifying unit 632 is 100. As depicted in FIG. 6, in this case, the output voltages of the high range amplifying unit 631 will be 40 millivolts and the resolution will be 0.107 dB/step. The output voltages of the low range amplifying unit 632 will be 1000 millivolts and the resolution will be 0.004 dB/step.

An example of specific designs of the PD receiving unit 610, the high range amplifying unit 631, and the low range amplifying unit 632 is explained. In this example, an optical receiving level range is −15.0 to +4.4 dBm, the resolution is 0.1 dB/Step, the PD photodetection sensitivity (characteristics of the PD device) is 0.017 to 0.080 mA/mW, and the full scale of the A/D converting unit 640 is 4000 millivolts.

As circuit designing conditions, the input offset voltage value of the operational amplifier 621 in the electrical level stabilizing unit 620 needs to be considered. Typical offset voltage value of the operational amplifier is equal to or less than about 3.5 millivolts. Therefore, the minimum voltage obtained from the PD receiving unit 610 is set to five millivolts or greater taking a margin into account and the resistance of the fixed resistor 612 is provisionally determined.

Under the conditions, the conditions having impacts on the offset voltage value are the minimum optical receiving level is −15.0 dBm and the PD photodetection sensitivity is 0.017 mA/mW. Under such conditions, exploiting Equation (1), the minimum output voltage of the PD 611 is calculated. This voltage value provisionally determines the resistance of the fixed resistor 612 to be five millivolts or greater.

In addition, the input voltage of the A/D converting unit 640 when the optical receiving level is maximum needs to be designed not to exceed the full scale. The maximum conditions correspond to the optical maximum receiving level is +4.4 dBm and the PD photodetection sensitivity=0.080 mA/mW. The output voltage Vout of the PD receiving unit 610 under such conditions is calculated using the resistance of the fixed resistor 612 provisionally determined above according to Equation (1).

Then, considering the gains of the electrical level stabilizing unit 620 and the high range amplifying unit 631, the output voltage of the high range amplifying unit 631 adjusts the resistance of the fixed resistor 612 so as not to exceed the full scale of the A/D converting unit 640.

Referring back to FIG. 2, the A/D converting unit 640 is a processor that digitizes the output voltages of the high range amplifying unit 631 and the low range amplifying unit 632. The digital processor 650 is a processor that digitally processes and outputs the voltage value digitized by the A/D converting unit 640. The digital processor 650 has a selecting unit 651, a logarithm converting unit 652, an output correcting unit 653, a read only memory (ROM) 654, and a nonvolatile memory 655.

The selecting unit 651 is a processor that selects and outputs one of the value digitized by the A/D converting unit 640 from the output voltage of the high range amplifying unit 631 and the value digitized by the A/D converting unit 640 from the output voltage of the low range amplifying unit 632 such that the selected one does not exceed the full scale of the A/D converting unit 640 and has higher resolution than the other.

More precisely, the selecting unit 651 outputs the voltage value digitized by the A/D converting unit 640 from the output voltage of the low range amplifying unit 632 if the voltage value digitized by the A/D converting unit 640 from the output voltage of the low range amplifying unit 632 does not exceed a threshold 654a stored in the ROM 654. Otherwise, the selecting unit 651 outputs the voltage value digitized by the A/D converting unit 640 from the output voltage of the high range amplifying unit 631.

In this case, the value of the threshold 654a is set to the full scale of the A/D converting unit 640, thereby enabling to effectively utilize high resolution of the output voltage of the low range amplifying unit 632. The voltage value digitized from the output voltage of the high range amplifying unit 631 may be compared with the threshold 654a to select the output.

The logarithm converting unit 652 is a processor that converts the output of the selecting unit 651 to a logarithm expression using a converting table 655a stored in the nonvolatile memory 655 including an erasable programmable read only memory (EPROM), and a flash memory to correct the exponential function characteristics. The logarithm converting unit 652 is realized with small circuit size because the logarithm conversion is performed with reference to the table having calculation results stored therein in advance, instead of calculating the logarithm conversion.

The threshold 654a may be stored in the nonvolatile memory 655 and the ROM 654 and the nonvolatile memory 655 may be shared by a circuit other than the optical detecting circuit 60.

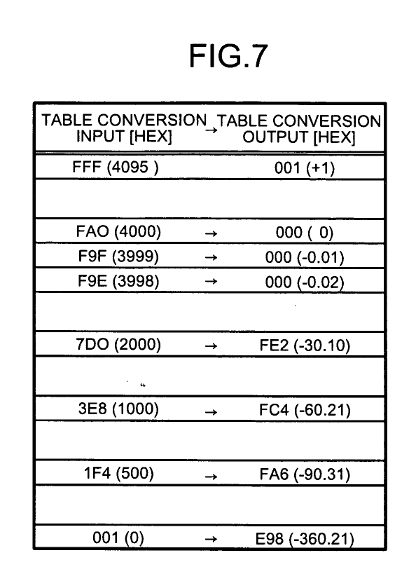

An example of the converting table 655a is depicted in FIG. 7. This table stores therein values calculated in advance using Equation (2) below.

$$Vo = \{ 10 \times Log ( \frac{Vi}{4000} ) \} \times 10 \qquad ( 2 )$$

where Vi is a voltage value before conversion and Vo is a voltage value after conversion.

The output correcting unit 653 is a processor that uses a correcting table 655b stored in the nonvolatile memory 655 to correct the output of the logarithm converting unit 652. The output of the output correcting unit 653 is the output of the optical detecting circuit 60. More precisely, the output correcting unit 653 obtains an optical monitor corrected value from the correcting table 655b to add this value to the output of the logarithm converting unit 652 and outputs the result using Equation (3) shown below.

Optical Input Level Value=Table-Converted Output+Optically Monitored Correction (3)

The optically monitored correction is preset for each output of the selecting unit 651, based on whether the amplifying is performed in the high range amplifying unit or not. More precisely, the computational output value PM is calculated according to Equations (4) and (5) below. The optically monitored correction is obtained as a difference between the computational output value and an experimentally obtained expected value Pref as shown in Equation (6):

$$\begin{matrix}PM = 10 \times Pin & ( 4 ) \\ Vo = 10 \times Log ( \frac{Vi}{η \times R 1 \times A 1 \times A 2} ) & ( 5 )\end{matrix}$$

P Optically Monitored Correction=Pref−PM (6)

where R1 is a resistance of the fixed resistor 612, A1 is a voltage gain of the electrical level stabilizing unit 620, and A2 is the voltage gain of the high range amplifying unit 631 or of the low range amplifying unit 632.

As described above, the optical detecting circuit 60 does not include the variable resistance, avoiding reduced accuracy resulted from the variable resistance. In addition, even when the optical input level is low and the output of the PD receiving unit 610 is low, the low range amplifying unit having high gain amplifies the output, so that sufficient resolution can be ensured. Further, the logarithm converting unit 652 and the output correcting unit 653 correct the exponential function characteristics of the output of the PD receiving unit 610 by obtaining pre-calculated value from the table. Therefore, a value can be output that is suitable for processing by a processor located downstream thereof in a simple circuit.

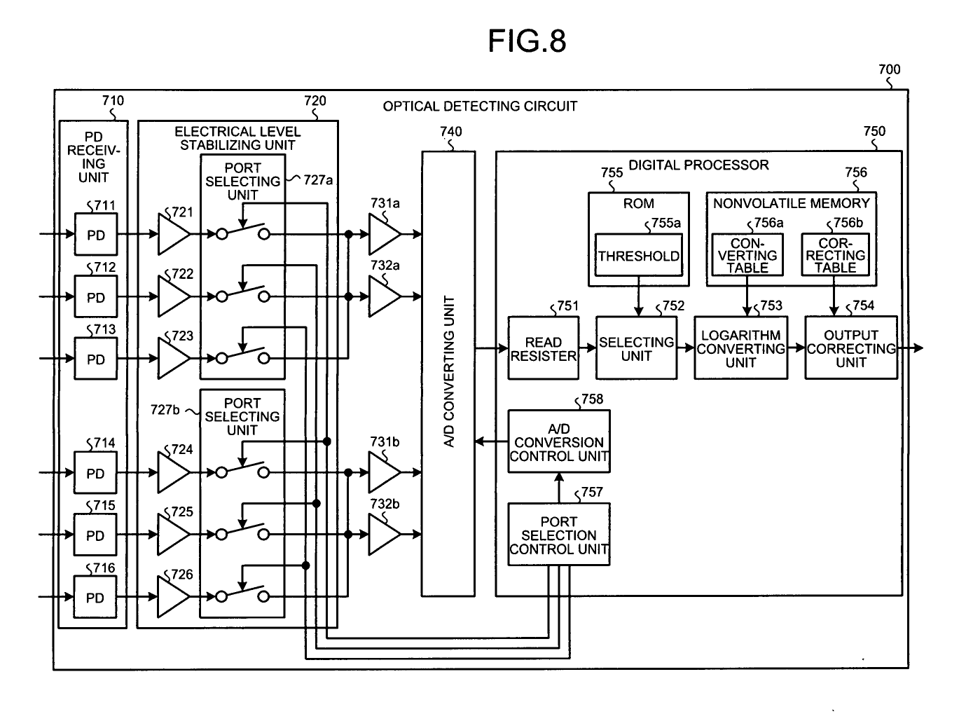

The example depicted in FIG. 2 includes the optical detecting circuit that detects the optical level of the optical signal having one wavelength. However, the optical detecting circuit can be configured to be able to detect the optical levels of the optical signals having a plurality of wavelengths. FIG. 8 is a block diagram of an optical detecting circuit 70 including six photodiodes. As depicted in FIG. 8, the optical detecting circuit 70 has a PD receiving unit 710, an electrical level stabilizing unit 720, high range amplifying units 731a and 731b, low range amplifying units 732a and 732b, an A/D converting unit 740, and a digital processor 750.

The PD receiving unit 710 has six PDs 711 to 716, each PD receiving different optical signal. In FIG. 8, the fixed resistor as the driving resistor is omitted. The output voltages of the PDs 711 to 716 are input to operational amplifiers 721 to 726 of the electrical level stabilizing unit 720.

The electrical level stabilizing unit 720 further has port selecting units 727a and 727b. The output of the operational amplifiers 721 to 723 are input to the port selecting unit 727a. The outputs of the operational amplifiers 724 to 726 are input to the port selecting unit 727b. The port selecting units 727a and 727b selects and outputs one of the inputs according to an instruction from a port selection control unit 757 in the digital processor 750.

The high range amplifying unit 731a amplifies the output voltage of the port selecting unit 727a by a predetermined gain. The low range amplifying unit 732a amplifies the output voltage of the port selecting unit 727a by a predetermined gain larger than that of the high range amplifying unit 731a. Similarly, the high range amplifying unit 731b amplifies the output voltage of the port selecting unit 727b by a predetermined gain. The low range amplifying unit 732b amplifies the output voltage of the port selecting unit 727b by a predetermined gain larger than that of the high range amplifying unit 731b.

The A/D converting unit 740 converts the output voltages of the high range amplifying units 731a and 731b and the low range amplifying units 732a and 732b to digital values and outputs the converted results. The A/D converting unit 740 switches the output voltage to be converted according to an instruction of an A/D converting control unit 758 in the digital processor 750.

The digital processor 750 has a read resister 751, a selecting unit 752, a logarithm converting unit 753, and an output correcting unit 754, a ROM 755, a nonvolatile memory 756, the port selection control unit 757, and the A/D converting control unit 758. The read resistor 751 is a storage unit that temporality stores therein the conversion results of the A/D converting unit 740.

The selecting unit 752, the logarithm converting unit 753, the output correcting unit 754, the ROM 755, and the nonvolatile memory 756 are similar to the selecting unit 651, the logarithm converting units 652, the output correcting unit 653, the ROM 654, and the nonvolatile memory 655 depicted in FIG. 2, respectively, and therefore, not explained further. Note that, the ROM 755 and the nonvolatile memory 756 may contain different values for each wavelength of the optical signal received at the PD receiving unit 710.

The port selection control unit 757 controls selection of the outputs in the port selecting units 727a and 727b. The A/D converting control unit 758 controls selection of the output to be converted in the A/D converting unit 740 in synchronization with the control by the port selection control unit 757. In this way, the optical detecting circuit 70 is configured to be able to share the digital processor while having six PDs based on the control by the port selection control unit 757 or the like, resulting in a small-size and low-cost circuit.

As described above, according to the present embodiment, as the amplifying unit that amplifies the voltage generated by the PD receiving unit, two amplifying units having different gains are provided to enable to select adequate one of the outputs of the amplifying unit by threshold determination. Therefore, the optical levels can be detected with high accuracy while maintaining a sufficient dynamic range.

Further, the digital value converted from the amplifying result are corrected using the stored correction value. Therefore, even when using an inexpensive operational amplifier as the amplifying unit, the exponential function characteristics of the output of the operational amplifier can be corrected with simple configuration, enabling to detect the optical levels with high accuracy and low costs.

According to the embodiments, as the amplifying unit that amplifies the voltage generated by the optical receiving unit, two amplifying units having different gains are provided to enable to select adequate one of outputs of the two amplifying units by threshold determination. Therefore, the optical level can be detected with high accuracy while maintaining a sufficient dynamic range.

According to the embodiments, a digital value of the amplifying result is corrected using a correction value stored in advance. Therefore, even when an inexpensive operational amplifier is used as an amplifying unit, exponential function characteristics of an output of the operational amplifier can be corrected in a simple manner to enable to detect the optical level with high accuracy and low costs.

According to the embodiments, a variable table is provided to correct the exponential function characteristics of the output of the amplifying unit. The exponential function characteristics are corrected using this table. Therefore, a correction amount of the exponential function characteristics and a correction amount resulted from the other factors are managed independently, resulting in minimized correction amount at modification of designs.

According to the embodiments, as a driving resistor for the optical receiving unit, instead of a variable resistor, a fixed resistor is used. Therefore, decrease in accuracy caused by fluctuation of the variable resistance can be prevented.

The components, expressions, or any combination of the components are validly applied to a method, an apparatus, a system, a computer program, a storage medium, a data structure, or the like according to the embodiments.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present inventions has been described in detail, it should be understood that the various changes, substitutions, and alterations could be made hereto without departing from the spirit and scope of the invention.

What is claimed is:

1. An optical detecting circuit that detects and outputs an optical level of input light, the optical detecting circuit comprising:
an optical receiving unit that generates voltage depending on the optical level of the input light;
a first amplifying unit that amplifies the voltage generated by the optical receiving unit;
a second amplifying unit that amplifies the voltage generated by the optical receiving unit by a gain larger than that of the first amplifying unit;
an A/D converting unit that digitizes voltage levels of output voltages of the first amplifying unit and the second amplifying unit;
a selecting unit that compares conversion results of the A/D converting unit with a threshold to select for output one of digitized values of the voltage levels of the output voltages of the first amplifying unit and the second amplifying unit; and
an output correcting unit that obtains a correction value depending on a selection result of the selecting unit from a storage unit to add the correction value to the value selected by the selecting unit.

2. The optical detecting circuit according to claim 1, further comprising a logarithm converting unit that converts the value selected by the selecting unit to a logarithm expression thereof based on a converting table stored in the storage unit in advance.

3. The optical detecting circuit according to claim 1, wherein the optical receiving unit uses a fixed resistor as a driving resistor.

4. An optical transmitting apparatus including an optical detecting circuit that detects and outputs an optical level of an optical signal amplified by an optical amplifier,
the optical detecting circuit comprising:
an optical receiving unit that generates voltage depending on the optical level of input light;
a first amplifying unit that amplifies the voltage generated by the optical receiving unit;
a second amplifying unit that amplifies the voltage generated by the optical receiving unit by a gain larger than that of the first amplifying unit;
an A/D converting unit that digitizes voltage levels of output voltages of the first amplifying unit and the second amplifying unit;
a selecting unit that compares conversion results of the A/D converting unit with a threshold to select for output one of digitized values of the voltage levels of the output voltages of the first amplifying unit and the second amplifying unit; and
an output correcting unit that obtains a correction value depending on a selection result of the selecting unit from a storage unit to add the correction value to the value selected by the selecting unit.

5. The optical transmitting apparatus according to claim 4, further comprising a logarithm converting unit that converts the value selected by the selecting unit to a logarithm expression thereof based on a converting table stored in the storage unit in advance.

6. The optical transmitting apparatus according to claim 4, wherein the optical receiving unit uses a fixed resistor as a driving resistor.

7. An optical detecting method for detecting and outputting an optical level of input light, the optical detecting method comprising:
generating voltage depending on the optical level of the input light by using a photo-detector;
amplifying the voltage generated at the generating by a first gain;
amplifying the voltage generated at the generating by a second gain larger than the first gain;
digitizing voltage levels of output voltages at the amplifying with the first and second gains;
comparing the digitized results at the digitizing with a threshold to select for output one of the digitized values of the voltage levels of the output voltages at the amplifying with the first and second gains; and
obtaining a correction value depending on the compared result at the comparing from a storage unit to add the correction value to the value selected at the comparing.

8. The optical detecting method according to claim 7, further comprising converting the value selected at the comparing to a logarithm expression thereof based on a converting table stored in the storage unit in advance.
